(19) United States
(12) Patent Application Publication
(10) Pub. No.: US 2024/0105880 A1
(43) Pub. Date: Mar. 28, 2024

(54) LIGHT-EMITTING DIODE AND DISPLAY DEVICE

(71) Applicant: Tianjin Sanan Optoelectronics Co., Ltd., Tianjin (CN)

(72) Inventors: Yuehua JIA, Tianjin (CN); Weifan KE, Tianjin (CN); Rongyan GUO, Tianjin (CN); Huanshao KUO, Tianjin (CN); Yuren PENG, Tianjin (CN); Duxiang WANG, Tianjin (CN)

(73) Assignee: Tianjin Sanan Optoelectronics Co., Ltd., Tianjin (CN)

(21) Appl. No.: 18/463,272

(22) Filed: Sep. 7, 2023

(30) Foreign Application Priority Data
Sep. 22, 2022 (CN) 202211156812.6

(51) Int. Cl. H01L 33/22; H01L 27/15; H01L 33/36

(52) U.S. Cl. CPC H01L 33/22; H01L 27/156; H01L 33/36; H01L 2933/0033

(57) ABSTRACT

A light-emitting diode and a display device are provided. The light-emitting diode includes an epitaxial structure, and the epitaxial structure has a light-emitting surface and a rear surface opposite to the light-emitting surface. The light-emitting surface includes a peripheral region and a middle region surrounded by the peripheral region, the peripheral region is covered with an insulating layer, and the area of the middle region accounts for 60% to 99% of the area of the light-emitting surface. The width of the insulating layer on the light-emitting surface is between 5 μm and 20 μm, so that it is possible to ensure a sufficient light output rate of the light-emitting diode, and the thickness of the insulating layer may be properly increased as well to enhance the protection for the sidewall of the light-emitting diode and prevent IR current leakage from affecting the performance of the device.

### CROSS-REFERENCE TO RELATED APPLICATION

This application claims the priority benefit of China application serial no. 202211156812.6, filed on Sep. 22, 2022. The entirety of the above-mentioned patent application is hereby incorporated by reference herein and made a part of this specification.

### BACKGROUND

### Technical Field

The disclosure relates to the technical field of semiconductor devices, in particular to a light-emitting diode and a display device.

### Description of Related Art

LED has received a lot of attention due to the characteristics of high luminous efficiency, long service life, safety, reliability, environmental protection and energy saving. In order to protect the LED from damages caused by external factors as much as possible, an insulating protective layer is generally formed on the light-emitting surface and the sidewall of the LED. The insulating protective layer covers all the light-emitting surfaces except the electrode structure, or covers portion of the electrode structure simultaneously. However, in order to ensure the light-emitting performance of the LED and prevent current leakage, strict requirements are imposed on the above-mentioned insulating protective layer. When the thickness of the insulating protective layer is less than 1000 Å, the insulating protective layer will not block light and will not affect the light-emitting efficiency of the LED, but there is a dramatic level of current leakage of LED. If the thickness of the insulating protective layer is increased, for example, to 50,000Å or more, the light output of the LED will be significantly affected, and the brightness will be considerably reduced.

Therefore, there is an urgent need for a solution that may ensure that a LED chip does not leak current and at the same time improve light-emitting efficiency thereof.

### SUMMARY

In view of the above-mentioned problems and defects existing in LEDs in the related art, the present disclosure provides a light-emitting diode and a display device. The light-emitting diode includes an epitaxial structure, and the epitaxial structure has a light-emitting surface and a rear surface opposite to the light-emitting surface. The light-emitting surface includes a peripheral region and a middle region surrounded by the peripheral region, the peripheral region is covered with an insulating layer, and the area of the middle region accounts for 60% to 99% of the area of the light-emitting surface. It is possible to ensure a sufficient light output rate of the light-emitting diode, and at the same time, the thickness of the insulating layer may be properly increased to enhance the protection for the sidewall of the light-emitting diode and prevent IR current leakage from affecting the performance of the device.

According to a first aspect of the present disclosure, there is provided a light-emitting diode, which includes an epitaxial structure, the epitaxial structure has a light-emitting surface and a rear surface opposite to the light-emitting surface. The light-emitting surface includes a peripheral region and a middle region surrounded by the peripheral region. The peripheral region is covered with an insulating layer, and the area of the middle region accounts for 60% to 99% of the area of the light-emitting surface.

Optionally, the width of the insulating layer on the light-emitting surface is between 5 μm and 20 μm.

Optionally, the light-emitting surface has a roughening structure, and the region with the roughening structure is a roughened region.

Optionally, the area of the roughened region accounts for 0% to 100% of the area of the middle region.

Optionally, the roughened region is located in the middle region.

Optionally, the roughened region is located in the middle region and a portion of the peripheral region, and the roughening structure in the peripheral region is distributed closely adjacent to the middle region.

Optionally, the roughened region is located in the middle region and the peripheral region.

Optionally, the periphery of the epitaxial structure is formed as a cutting line of the light-emitting diode, and the width of the cutting line is between 10 μm and 30 μm.

Optionally, the epitaxial structure includes a semiconductor layer of a first conductivity type, a light-emitting layer, and a semiconductor layer of a second conductivity type stacked in sequence from the light-emitting surface to the rear surface, and the semiconductor layer of the first conductivity type serves as the light-emitting surface.

Optionally, a first electrode and an extended electrode that are connected to the semiconductor layer of the first conductivity type are formed above the middle region, and a surface of the extended electrode is covered with another insulating layer.

Optionally, a region of the middle region except for the first electrode and the extended electrode has a roughening structure.

Optionally, a reflective layer is formed on the rear surface of the epitaxial structure, and a substrate is bonded to a surface of the reflective layer.

Optionally, the sidewall of the epitaxial structure has a roughening structure.

According to a second aspect of the present disclosure, there is provided a display device, which includes: a housing, and a light-emitting unit disposed in the housing, the light-emitting unit is the light-emitting diode provided in the first aspect of the present disclosure.

As mentioned above, the light-emitting diode and display device of the present disclosure have the following advantageous effects.

The light-emitting diode of the present disclosure includes an epitaxial structure, the epitaxial structure has a light-emitting surface and a rear surface opposite to the light-emitting surface. The light-emitting surface includes a peripheral region and a middle region surrounded by the peripheral region, and the peripheral region is covered by an insulating layer, the area of the middle region accounts for 60% to 99% of the area of the light-emitting surface. The width of the insulating layer on the light-emitting surface is between 5 μm and 20 μm, so as to ensure sufficient light-emitting area of the light-emitting diode, and at the same time, the thickness of the insulating layer may be properly increased to enhance the protection for the sidewall of the light-emitting diode, thus preventing IR current leakage from affecting the performance of the device.

In addition, the light-emitting surface of the light-emitting diode of the present disclosure has a roughened region, and the area of the roughened region accounts for 0% to 100% of the area of the light-emitting surface, that is, the roughened region may be formed on the light-emitting surface in any proportion. The roughening structure in the roughened region helps to further improve the light-emitting efficiency of the light-emitting diode. Preferably, the peripheral region covered by the first insulating layer may be partially roughened or not roughened at all, or more preferably, the distance between the roughened region and the insulating layer is between 3 μm and 10 μm, and the above arrangement of the roughened region ensures that a portion or all of the region covered by the first insulating layer is a flat surface, thereby increasing the adhesion of the insulating layer, preventing IR current leakage.

### BRIEF DESCRIPTION OF THE DRAWINGS

FIG. 1 is a schematic structural view of a light-emitting diode in the related art.

FIG. 2 shows a schematic structural view of a light-emitting diode provided in Embodiment 1 of the present disclosure.

FIG. 3 is a schematic top view of the light-emitting diode shown in FIG. 2.

FIG. 4 shows a schematic structural view of the light-emitting diode provided for Embodiment 2.

FIG. 5 shows a schematic structural view of a light-emitting diode provided for an alternative embodiment of the Embodiment 2.

FIG. 6 shows a schematic structural view of a light-emitting diode provided for another alternative embodiment of the Embodiment 2.

FIG. 7 shows a schematic structural view of a light-emitting diode provided for another alternative embodiment of the Embodiment 2.

FIG. 8 shows a schematic structural view of the light-emitting diode provided in Embodiment 3 of the present disclosure.

FIG. 9 shows a schematic structural view of a light-emitting device provided in Embodiment 4 of the present disclosure.

### DESCRIPTION OF THE EMBODIMENTS

Embodiments of the present disclosure are described below through specific examples, and those skilled in the art can easily understand other advantages and effects of the present disclosure from the content disclosed in this specification. The present disclosure can also be implemented or applied through other different specific implementation modes, and various modifications or changes can be made to the details in this specification based on different viewpoints and applications without departing from the spirit of the present disclosure.

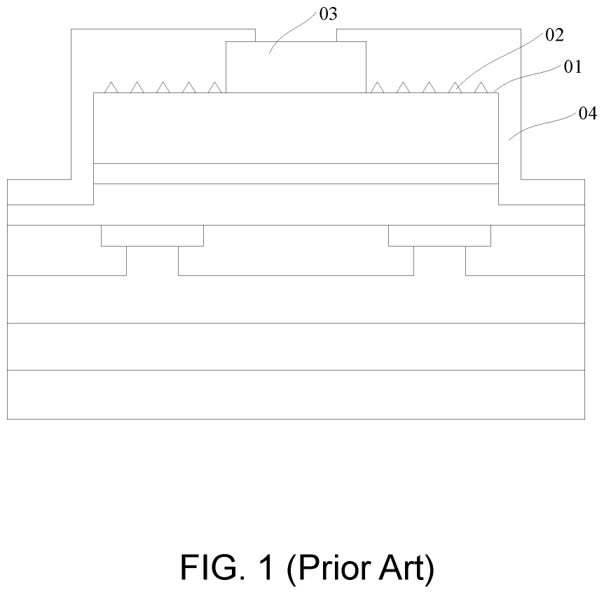

As shown in FIG. 1, in the related art, in order to improve the light-emitting efficiency of the light-emitting diode, a roughening structure 02 is generally formed on the light-emitting surface 01 of the light-emitting diode, so that the light-emitting surface 01 forms a roughened surface, and further, the sidewall of the light-emitting diode may be formed into a roughened surface. In order to protect the light-emitting diode from IR current leakage, an insulating protective layer 04 is generally provided on the sidewall and exposed surface of the light-emitting diode. In the related art, the insulating protective layer 04 is formed on the sidewall and the light-emitting surface 01 of the light-emitting diode, and also covers a portion of the surface of the electrode structure 03 on the light-emitting surface 01. Such an insulating protective layer is able to suppress IR current leakage to a certain extent, but the insulating protective layer 04 is formed on almost the entire light-emitting surface 01, which dramatically affects the light-emitting efficiency of the light-emitting diode. In addition, in order to ensure the light-emitting performance of the LED and prevent current leakage, strict requirements are imposed on the above-mentioned insulating protective layer. When the thickness of the insulating protective layer is less than 1000 Å, the insulating protective layer will not block light and will not affect the light-emitting efficiency of the LED, but there is a dramatic level of current leakage of LED. If the thickness of the insulating protective layer is increased, for example, to 50,000 Å or more, the light output of the LED will be dramatically affected, and the brightness thereof will be significantly reduced.

### Embodiment 1

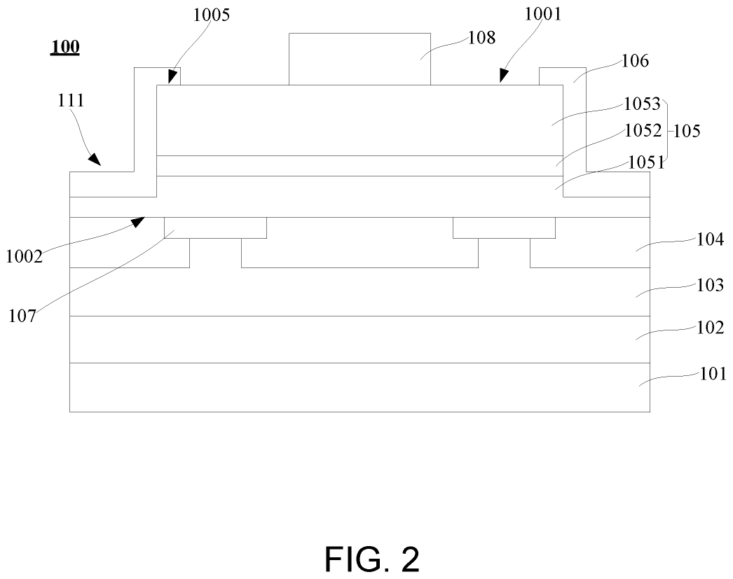

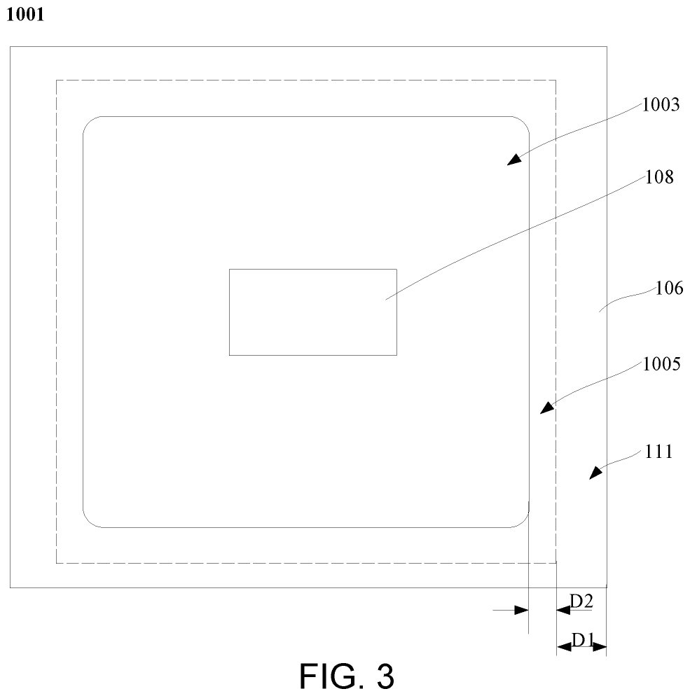

In view of the above defects, this embodiment provides a light-emitting diode 100, as shown in FIG. 2, the light-emitting diode 100 includes an epitaxial structure 105, the epitaxial structure 105 has a light-emitting surface 1001 and a rear surface 1002 opposite to the light-emitting surface 1001. Referring to FIG. 3 at the same time, the light-emitting surface 1001 includes a peripheral region 1005 and a middle region 1003 surrounded by the peripheral region 1005. In this embodiment, the area of the middle region 1003 accounts for 60% to 99% of the area of the light-emitting surface 1001. As shown in FIG. 2 and FIG. 3, the peripheral region 1005 of the light-emitting surface 1001 is covered with a first insulating layer 106, and the width D2 of the peripheral region 1005 covered by the first insulating layer 106 is between 5 μm and 20 μm, preferably, between 5 μm and 7 μm, thereby ensuring that the ratio of the area of middle region 1003 to the area of the light-emitting surface 1001 is between 60% and 99%. As mentioned above, in this embodiment, the first insulating layer 106 only covers the peripheral region 1005 of the light-emitting surface 1001, and the shielded region is significantly reduced, thereby reducing the absorption of light emitted by the epitaxial structure 105 by the first insulating layer 106. In addition, the middle region 1003 is not covered by an insulating layer, and the light emitted by the epitaxial structure 105 from the middle region will not be absorbed, thus improving the light-emitting efficiency of the light-emitting diode 100.

Also referring to FIG. 2, the first insulating layer 106 is also formed on the sidewall of the epitaxial structure 105, thereby protecting the epitaxial structure 105 from IR current leakage. In this embodiment, the first insulating layer 106 is formed on the sidewall of the epitaxial structure 105 and the peripheral region 1005 of the light-emitting surface 1001, which will not affect the light-emitting rate of the middle region 1003, so the thickness of the first insulating layer 106 may be properly increased. For example, the thickness of the first insulating layer 106 ranges from 3 μm to 10 μm, preferably around 5 μm, thereby simultaneously increasing the protection for the sidewall, and further preventing IR current leakage, and ensuring the yield of the device. Optionally, the first insulating layer 106 may be a transparent insulating oxide, such as a combination of one or more of SiOx, SiNx, TiOx, and Al₂O₃, and the above-mentioned first insulating layer 106 may be formed by evaporation, chemical deposition, atomic force deposition, etc., thereby ensuring the thickness and uniformity of the first insulating layer 106.

As shown in FIG. 2, the epitaxial structure 105 of the light-emitting diode 100 in this embodiment includes a semiconductor layer 1053 of the first conductivity type, a light-emitting layer 1052 and a semiconductor layer 1051 of the second conductivity type stacked in sequence from the light-emitting surface 1001 to the rear surface 1002, and the semiconductor layer 1053 of the first conductivity type forms the above-mentioned light-emitting surface 1001. The above-mentioned epitaxial structure 105 is etched from the semiconductor layer 1053 of the first conductivity type to the semiconductor layer 1051 of the second conductivity type to form a cutting line 111. The cutting line 111 is configured for cutting the light-emitting diode 100 subsequently to obtain independent dies. The cutting line 111 exposes the sidewall of the epitaxial structure 105, and the first insulating layer 106 is formed on the sidewall and the surface of the cutting line 111 simultaneously to protect the sidewall and exposed surface of the epitaxial layer. As shown in FIG. 3, the width D1 of the cutting line 111 is between 10 μm and 30 μm, preferably between 15 μm and 20 μm, and this width may ensure the adhesion of the first insulating layer 106 and will not cause any damage or destruction during subsequent cutting.

The semiconductor layer 1051 of the second conductivity type may be an N-type semiconductor layer, and the semiconductor layer 1053 of the first conductivity type may be a P-type semiconductor layer. It may be understood that, a surface of the semiconductor layer 1053 of the first conductivity type on one side away from the light-emitting layer may also be formed with a structure such as a transparent conductive layer. In an optional embodiment, the semiconductor layer 1051 of the second conductivity type may be an N-type AlGaInP layer, the light-emitting layer 1052 is a quantum well layer, and the semiconductor layer 1053 of the first conductivity type is a P-type AlGaInP layer. Alternatively, the semiconductor layer 1051 of the second conductivity type may be an N-type AlGaInP layer, the light-emitting layer 1052 may be an AlGaInP/AlGaInP multiple quantum well, and the semiconductor layer 1053 of the first conductivity type may be a P-type AlGaInP layer. The material of the semiconductor layer of the second conductivity type in this embodiment may also be a GaN-based material.

In this embodiment, the light-emitting diode 100 has a vertical structure, and a first electrode 108 is formed on the light-emitting surface 1001, and the first electrode 108 is electrically connected to the semiconductor layer 1053 of the first conductivity type. As shown in FIG. 2, in a direction gradually away from the rear surface 1002, the rear surface 1002 of the epitaxial layer has a current blocking layer 104, a reflective layer 103, a bonding layer 102 and a substrate 101 formed in sequence, and the bonding layer 102 bonds the substrate 101 to the epitaxial structure 105 together.

The current blocking layer 104 may be formed of an insulating material having conductivity less than that of the reflective layer 103, a material having low conductivity, or a material Schottky-contacting the semiconductor layer of the second conductivity type. For example, the current blocking layer 104 may be composed of at least one of fluoride, nitride or oxide, and specifically formed by, for example, at least one of ZnO, SiO₂, SiOx, SiOxNy, Si₃N₄, Al₂O₃, TiOx, MgF or GaF. An ohmic contact layer 107 is further formed between the current blocking layer 104 and the semiconductor layer 1051 of the second conductivity type. The ohmic contact layer 107 is preferably formed in a plurality of openings of the current blocking layer 104 to contact the semiconductor layer 1051 of the second conductivity type. In a preferred embodiment, the ohmic contact layer 107 is an ITO contact layer with transparent material. Optionally, the above-mentioned ohmic contact layer 107 may also be other transparent materials or metal materials, such as transparent conductive materials like IZO, IZTO, IAZO, IGZO, IGTO, AZO or ATO, or may be metallic material such as AuZn, AuBe, GeNi, etc. Preferably, the reflective layer 103 in this embodiment is a metal reflective layer 103, so the reflective layer 103 may serve as a connection layer for forming a second electrode. Optionally, the reflective layer 103 may be formed of at least one metal or alloy, including Ag, Ni, Al, Rh, Pd, Jr, Ru, Mg, Zn, Pt, Au and Hf. The reflective layer 103 reflects the light emitted by the light-emitting layer 1052 so that the light exit from the light-emitting surface 1001.

As shown in FIG. 2, the reflective layer 103 is connected to the ohmic contact layer 107 through an opening in the current blocking layer 104 corresponding to the ohmic contact layer 107. The bonding layer 102 is also a metal bonding layer 102, for example, the bonding layer 102 may be a combination of one or more metals such as gold, tin, titanium, nickel, platinum, etc., and the bonding layer 102 may be a single-layer structure or a multilayer structure. The substrate 101 is bonded to the epitaxial structure 105 through the bonding layer 102, and the substrate 101 may be a conductive substrate 101 or an insulating substrate 101. When the substrate 101 is a conductive substrate 101, the substrate 101 may directly serve as the second electrode, and be connected to the semiconductor layer 1051 of the second conductivity type through the bonding layer 102, the reflective layer 103, and the ohmic contact layer 107. When the substrate 101 is an insulating substrate 101, a second electrode (not specifically shown) may be formed by depositing a metal layer on the surface of the substrate 101 and through the connection with the bonding layer 102 by means of a through-hole process.

### Embodiment 2

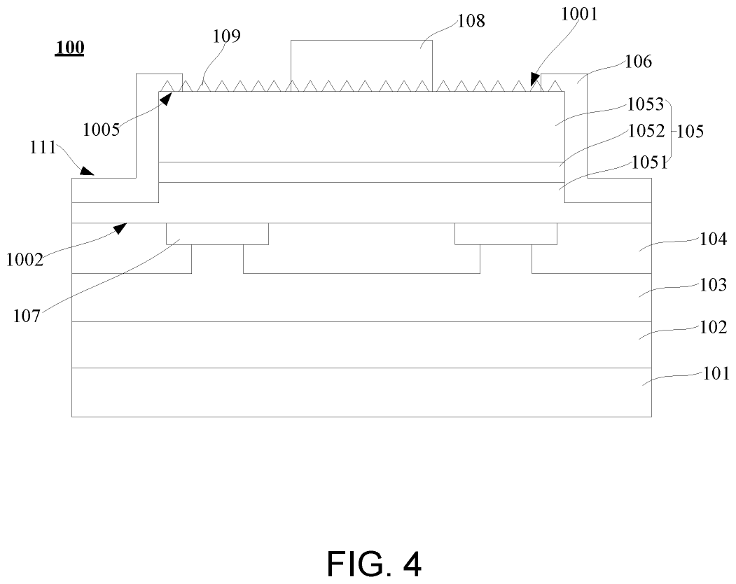

This embodiment also provides a light-emitting diode 100. As shown in FIG. 4 to FIG. 7, the light-emitting diode 100 also includes an epitaxial structure 105, and the epitaxial structure 105 has a light-emitting surface 1001 and a rear surface 1002 opposite to the light-emitting surface 1001. The light-emitting surface 1001 includes a peripheral region 1005 and a middle region 1003 surrounded by the peripheral region 1005. In this embodiment, the area of the middle region 1003 accounts for 60% to 99% of the area of the light-emitting surface 1001. The similarities between Embodiment 2 and the light-emitting diode 100 of Embodiment 1 will not be repeated, and the difference between them is described as follows.

As shown in FIG. 4, the light-emitting surface 1001 of the light-emitting diode 100 of this embodiment forms a roughening structure 109, and the region where the roughening structure 109 is distributed forms a roughened region. The above-mentioned roughening structure 109 may be a nano-microstructure, and the roughening structure 109 causes the surface roughness of the roughened region between 0.2 μm and 1 μm. The nano-microstructure in the roughened region may increase the extraction rate of light and improve the light-emitting efficiency of the light-emitting diode 100.

In this embodiment, the area of the roughened region accounts for 0% to 100% of the area of the light-emitting surface 1001, that is, the roughened region may be distributed on the light-emitting surface 1001 in any proportion. As shown in FIG. 4, in an optional embodiment, the aforementioned roughening structure 109 is formed on the entire light-emitting surface 1001, that is, the area of the roughened region accounts for 100% of the area of the light-emitting surface 1001. The peripheral region 1005 covered by the insulating layer 106 also forms a roughening structure 109, so the light extraction rate of the region covered by the insulating layer may also be improved, so that the light extraction rate of the light-emitting surface 101 may be improved, and the light-emitting efficiency of the light-emitting diode may be increased.

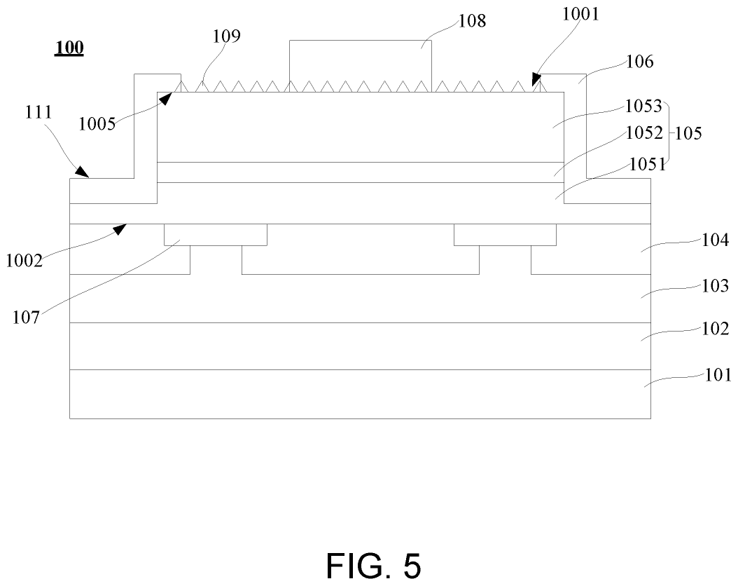

In another optional embodiment of this embodiment, as shown in FIG. 5, the roughening structure 109 is formed in the middle region 1003 and a portion of the peripheral region 1005, that is, the peripheral region 1005 is not completely roughened. Preferably, the roughening structure 109 of the peripheral region 1005 is formed in a region away from the cutting line 111, that is, formed in a region closely adjacent to the middle region 1003. When the width of the first insulating layer 106 on the light-emitting surface 1001 is between 5 μm and 20 μm, the width of the peripheral region 1005 not being roughened is between 3 μm and 10 μm. The above-mentioned distribution of the roughening structure 109 makes a portion of the covered region of the first insulating layer 106 a flat region, which enhances the adhesion of the first insulating layer 106 while increasing the light extraction rate of the light-emitting diode.

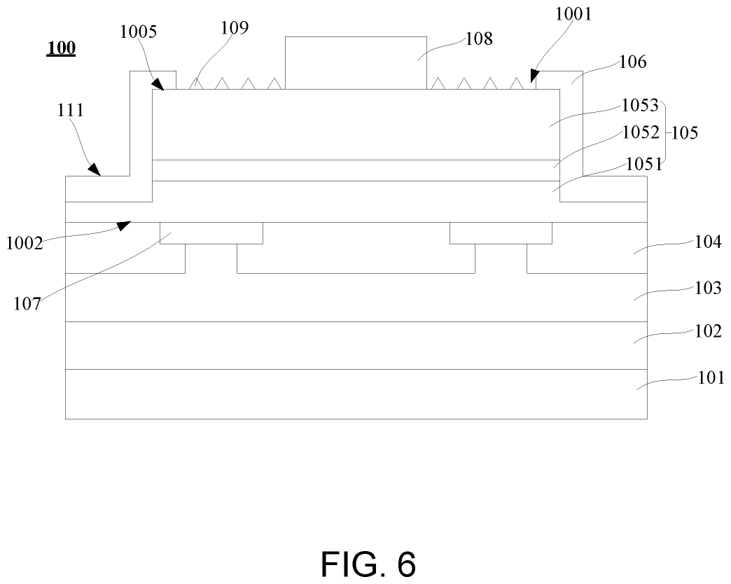

In yet another optional embodiment of this embodiment, as shown in FIG. 6, the roughening structure 109 is only formed in the middle region 1003, that is, the roughened region is located in the middle region 1003, and the above setting makes the area of the roughened region account for 60% to 99% of the area of the middle region 1003. For example, for a die with a size (that is, the side length of the die) of 120 μm, the width of the light-emitting surface 1001 is set to be about 90 μm, and the width of the roughened region (that is, the middle region 1003) is about 80 μm. In this way, the ratio of area of the roughened region (i.e., the middle region 1003) to the area of the middle region is about 79%. For a die with a larger size, for example, for a die with a size (i.e., the side length of the die) of 1520 μm, the width of the light-emitting surface 1001 is about 1480 μm, and the width of the roughened region (i.e., the middle region 1003) is about 1470 μm. In this way, the ratio of the area of the roughened region to the area of the light-emitting region is about 98.6%, that is, close to 99%. The above setting of the roughened region makes the first insulating layer 106 not cover the roughened region, so that the light-emitting efficiency of the roughened region will not be affected, which helps to further improve the light-emitting efficiency of the light-emitting diode 100. In the meantime, because the peripheral region 1005 is a flat surface, the adhesion of the first insulating layer 106 is enhanced and current leakage may be avoided.

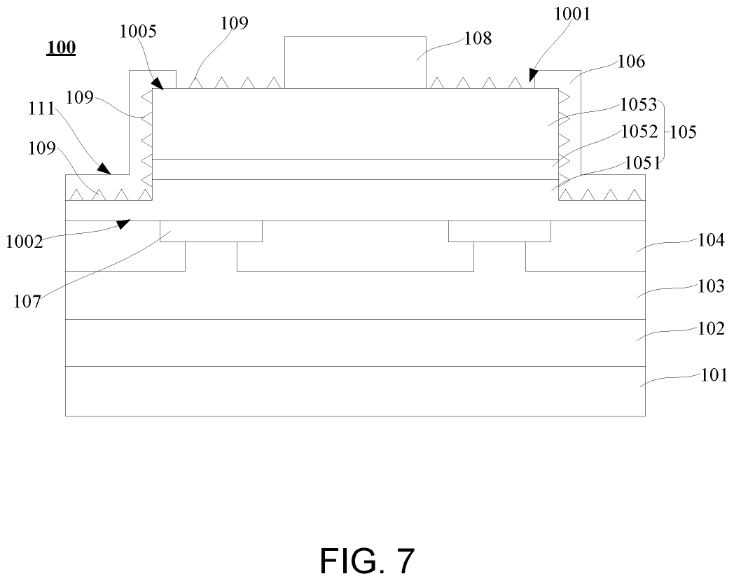

In another optional embodiment of this embodiment, as shown in FIG. 7, the roughening structure 109 is also formed on the sidewall of the epitaxial structure 105 and the surface of the cutting line 111. The aforementioned roughening structure 109 may also increase the extraction rate of light emitted by the epitaxial structure 105 and improve the light-emitting efficiency of the light-emitting diode. Regarding the roughening structure 109 on the light-emitting surface 1001, although FIG. 7 shows that the above-mentioned roughening structure 109 is formed in the middle region 1003 of the light-emitting surface 1001, it should be understood that, as shown in FIG. 2, the light-emitting surface 1001 is not formed with the roughening structure 109; or as shown in FIG. 4, the roughening structure 109 is formed on the entire light-emitting surface 1001; or as shown in FIG. 5, the roughening structure 109 is formed in the middle region 1003 and a portion of the peripheral region 1005.

### Embodiment 3

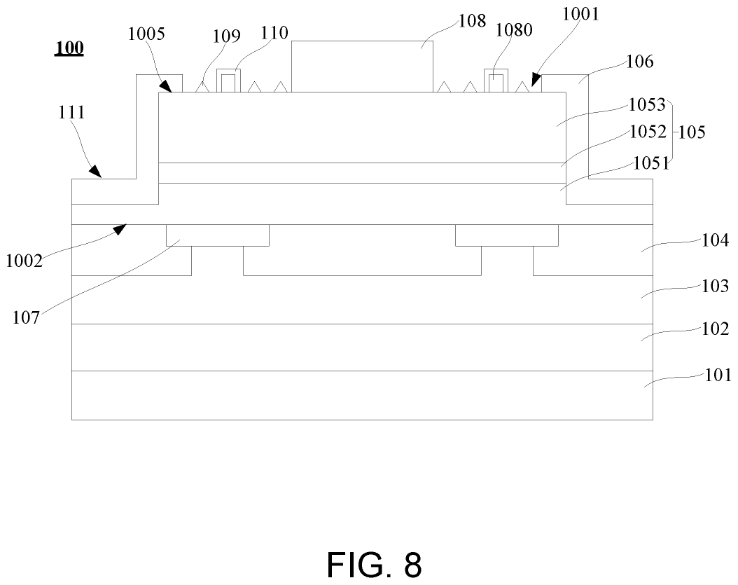

This embodiment also provides a light-emitting diode 100, as shown in FIG. 8, the light-emitting diode 100 also includes an epitaxial structure 105, and the epitaxial structure 105 has a light-emitting surface 1001 and a rear surface 1002 opposite to the light-emitting surface 1001. The light-emitting surface 1001 includes a peripheral region 1005 and a middle region 1003 surrounded by the peripheral region 1005. In this embodiment, the area of the middle region 1003 accounts for 60% to 99% of the area of the light-emitting surface 1001. The similarities between Embodiment 3 and the light-emitting diode 100 of Embodiment 1 and Embodiment 2 will not be repeated, and the difference between them is described as follows.

As shown in FIG. 8, in this embodiment, an extended electrode 1080 is formed on the light-emitting surface 1001 of the light-emitting diode 100, and the extended electrode 1080 is formed into a strip structure spaced apart from the first electrode 108. The extended electrode 1080 may enhance the lateral extension of the current, thereby improving the light-emitting efficiency of the light-emitting diode 100. Also as shown in FIG. 8, the surface of the extended electrode 1080 is covered with a second insulating layer 110. The second insulating layer 110 may protect the extended electrode 1080 from damage, and at the same time avoid defects such as current leakage or short circuit caused by the extended electrode 1080, and improve the yield rate of the device. The above-mentioned second insulating layer 110 may be formed of the same material as that of the first insulating layer 106, or may be formed of a different material. Preferably, the first insulating layer 106 and the second insulating layer 110 are made of the same insulating material, which may shorten the manufacturing process and help reduce the manufacturing cost of the device.

### Embodiment 4

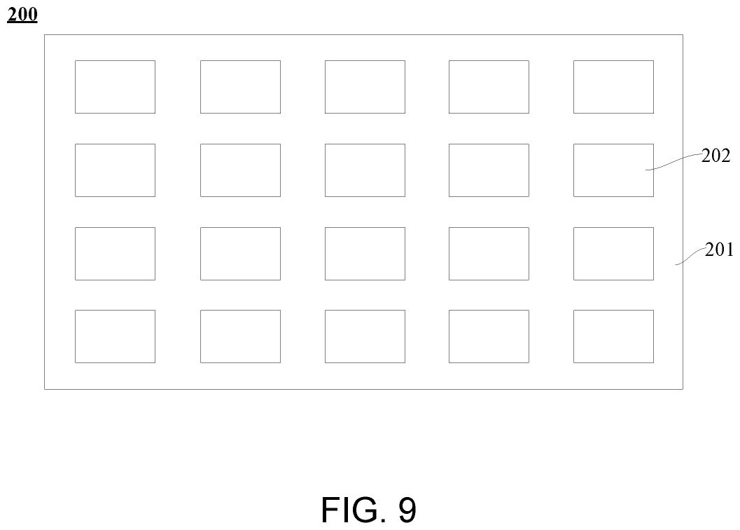

This embodiment provides an LED display device 200. As shown in FIG. 9, the LED display device 200 includes a housing 201 and a light-emitting unit 202 disposed in the housing 201. The light-emitting unit 202 may be the light-emitting diode 100 provided in the Embodiment 1, the Embodiment 2 or the Embodiment 3; or may be a combination of any two or three light-emitting diodes 100 provided in Embodiment 1, Embodiment 2 and Embodiment 3. The above-mentioned embodiments only illustrate the principles and effects of the present disclosure, but are not intended to limit the disclosure. Anyone skilled in the art can modify or change the above-mentioned embodiments without departing from the spirit and scope of the present disclosure. Therefore, all equivalent modifications or changes made by those skilled in the art without departing from the spirit and technical ideas disclosed in the present disclosure should still be compassed in the claims of the present disclosure.

What is claimed is:

1. A light-emitting diode, comprising an epitaxial structure, wherein the epitaxial structure has a light-emitting surface and a rear surface opposite to the light-emitting surface, the light-emitting surface comprises a peripheral region and a middle region surrounded by the peripheral region, the peripheral region is covered with a first insulating layer, wherein an area of the middle region accounts for 60% to 99% of an area of the light-emitting surface.

2. The light-emitting diode according to claim 1, wherein a width of the first insulating layer on the light-emitting surface is between 5 μm and 20 μm.

3. The light-emitting diode according to claim 1, wherein the light-emitting surface has a roughening structure, and a region with the roughening structure is a roughened region.

4. The light-emitting diode according to claim 3, wherein an area of the roughened region accounts for 0% to 100% of the area of the light-emitting surface.

5. The light-emitting diode according to claim 4, wherein the roughened region is located in the middle region.

6. The light-emitting diode according to claim 4, wherein the roughened region is located in the middle region and a portion of the peripheral region, and the roughening structure in the peripheral region is distributed closely adjacent to the middle region.

7. The light-emitting diode according to claim 4, wherein the roughened region is located in the middle region and the peripheral region.

8. The light-emitting diode according to claim 1, wherein a periphery of the epitaxial structure is formed as a cutting line of the light-emitting diode, and a width of the cutting line is between 10 μm and 30 μm.

9. The light-emitting diode according to claim 1, wherein the epitaxial structure comprises a semiconductor layer of a first conductivity type, a light-emitting layer, and a semiconductor layer of a second conductivity type stacked in sequence from the light-emitting surface to the rear surface, wherein the semiconductor layer of the first conductivity type serves as the light-emitting surface.

10. The light-emitting diode according to claim 9, wherein a first electrode and an extended electrode that are connected to the semiconductor layer of the first conductivity type are formed above the middle region, and a surface of the extended electrode is covered with a second insulating layer.

11. The light-emitting diode according to claim 10, wherein a region of the middle region except for the first electrode and the extended electrode has a roughening structure.

12. The light-emitting diode according to claim 9, wherein a reflective layer is formed on the rear surface of the epitaxial structure, and a substrate is bonded to a surface of the reflective layer.

13. The light-emitting diode according to claim 1, wherein a sidewall of the epitaxial structure has a roughening structure.

14. A display device, comprising: a housing, and a light-emitting unit disposed in the housing, wherein the light-emitting unit is the light-emitting diode according to claim 1.
